(19) United States
(12) Patent Application Publication
(10) Pub. No.: US 2025/0183149 A1
(43) Pub. Date: Jun. 5, 2025

(54) ELECTRONIC DEVICE

(71) Applicant: Innolux Corporation, Miaoli County (TW)

(72) Inventors: Shuo-Ting Hong, Miaoli County (TW); Chung-Le Chen, Miaoli County (TW); Hung-Kun Chen, Miaoli County (TW); Cheng-Tso Chen, Miaoli County (TW)

(73) Assignee: Innolux Corporation, Miaoli County (TW)

(21) Appl. No.: 18/940,739

(22) Filed: Nov. 7, 2024

(30) Foreign Application Priority Data
Dec. 5, 2023 (CN) 202311652739.6

(51) Int. Cl. H01L 23/498; G09G 3/20

(52) U.S. Cl. CPC H01L 23/49838; G09G 3/20; G09G 2310/0297

(57) ABSTRACT

An electronic device including a substrate, a first fan-out line, a second fan-out line, and a multiplexer circuit is disclosed. The substrate has an active area and a fan-out area. The first fan-out line is located in the fan-out area and has a first segment. The second fan-out line is located in the fan-out area and has a second segment. The first segment overlaps the second segment. A multiplexer circuit is located between the active area and the fan-out area and coupled to the first fan-out line and the second fan-out line. The first fan-out line receives a first data signal and the second fan-out line receives a second data signal. Polarities of the first data signal and the second data signal are opposite.

### CROSS-REFERENCE TO RELATED APPLICATION

This application claims the priority benefit of China application serial no. 202311652739.6, filed on Dec. 5, 2023. The entirety of the above-mentioned patent application is hereby incorporated by reference herein and made a part of this specification.

### BACKGROUND

### Technical Field

This disclosure relates to an electronic device with a display function.

### Description of Related Art

Display devices with multiplexer circuits have a frequency conversion function. When the display device is converted to a low frequency, the human eye can easily see gray-scale flickering due to the low frame rate, which reduces the display quality of the display device. The reason for this is that the difference in the length of the fan-out lines causes the voltage on the data line to be unevenly distributed.

### SUMMARY

According to the embodiment of the disclosure, an electronic device includes a substrate, a first fan-out line, a second fan-out line, and a multiplexer circuit. The substrate has an active area and a fan-out area. A first fan-out line is located in the fan-out area and has a first segment. A second fan-out line is located in the fan-out area and has a second segment. The first segment overlaps with the second segment. The multiplexer circuit is located between the active area and the fan-out area and coupled to the first fan-out line and the second fan-out line. The first fan-out line receives a first data signal, and the second fan-out line receives a second data signal. Polarities of the first data signal and the second data signal are opposite.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 shows a block diagram of an electronic device according to an embodiment of the disclosure.

FIG. 2 shows a detailed schematic diagram of the electronic device of the embodiment of FIG. 1.

FIG. 3 shows a schematic diagram of a fan-out line of the embodiment of FIG. 1.

FIG. 4 shows a schematic diagram of a partial segment of a fan-out line according to an embodiment of the disclosure.

FIG. 5 shows a schematic diagram of a partial segment of a fan-out line according to another embodiment of the disclosure.

### DESCRIPTION OF THE EMBODIMENTS

The disclosure can be understood by referring to the following detailed description in combination with the accompanying drawings. It should be noted that, in order to make it easy for readers to understand and for the simplicity of the drawings, many of the drawings in the disclosure only show a part of the electronic device, and certain elements in the drawings are not drawn to actual scale. In addition, the number and size of each element in the figures are only for illustration and are not intended to limit the scope of the disclosure.

In the following specification and claims, the words “include” and “comprise” are open-ended words, and therefore they should be interpreted to mean “includes but is not limited to . . . ”.

It should be understood that although the terms first, second, third . . . can be used to describe various constituent elements, the constituent elements are not limited to these terms. The term is only used to distinguish a single element from other elements in the specification. The same terms may not be used in the claims, but may be replaced by first, second, third . . . according to the order in which the elements are declared in the claims. Therefore, in the following specification, the first element may be the second element in the claims.

In some embodiments of the disclosure, terms related to joining and connecting, such as “connected”, “interconnected”, etc., unless otherwise defined, may mean that two structures are in direct contact, or may also mean that two structures are not in direct contact, and there are other structures located between these two structures. And the terms about joining and connecting can also include the situation where both structures are movable, or both structures are fixed. In addition, the term “coupling” includes any direct and indirect means of electrical connection. In the case of direct electrical connection, the end points of the elements on the two circuits are directly connected or connected to each other with a conductor line segment. In the case of indirect electrical connection, there are switches, diodes, capacitors, inductors, resistors, other suitable elements, or a combination of the above elements between the end points of the elements on the two circuits, but are not limited thereto.

An electronic device of the disclosure may include a display device, an antenna device, a sensing device, a light emitting device, or a splicing device, but is not limited thereto. The electronic device may include bendable or flexible electronic device. The electronic device may include electronic elements. The electronic device includes, for example, a liquid crystal layer or a light emitting diode (LED). The electronic elements may include passive elements and active elements, such as capacitors, resistors, inductors, variable capacitors, filters, diodes, transistors, sensors, microelectromechanical systems (MEMS), liquid crystal chips, controllers, etc., but not limited thereto. The diodes may include light emitting diodes or photodiodes. The light emitting diodes may include, for example, organic light emitting diodes (OLEDs), sub-millimeter light emitting diodes (mini LEDs), micro light emitting diodes (micro LEDs), quantum dot LEDs (quantum dot LEDs), fluorescence, phosphor, or other suitable materials, or a combination of the above, but not limited thereto. The sensors may include, for example, capacitive sensors, optical sensors, electromagnetic sensors, fingerprint sensors (FPS), touch sensors, antennas, or pen sensors, etc., but not limited thereto. The controllers may include, for example, a timing controller, but is not limited thereto. In the following, a display device will be used as an electronic device to illustrate the disclosure, but the disclosure is not limited thereto.

Reference will now be made in detail to the exemplary embodiments of the disclosure, examples of which are illustrated in the accompanying drawings. Whenever possible, the same reference numbers are used in the drawings and descriptions to refer to the same or similar parts.

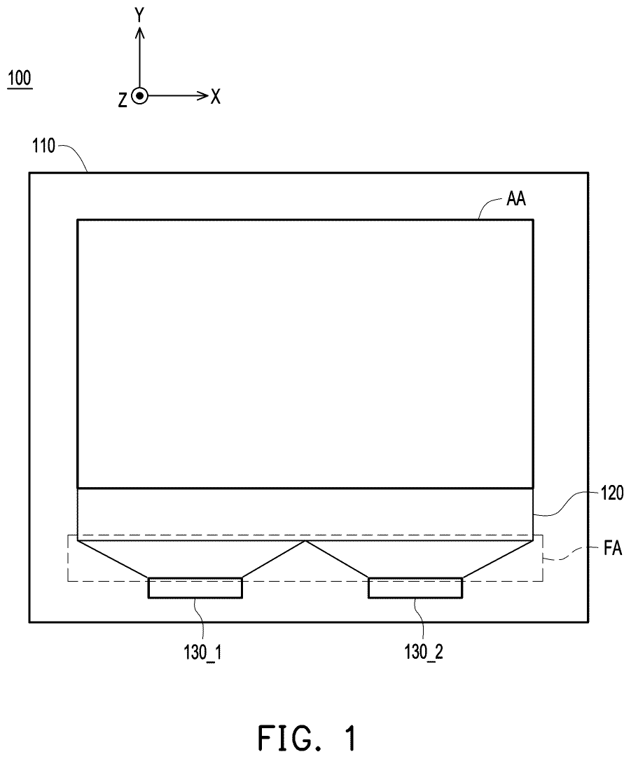

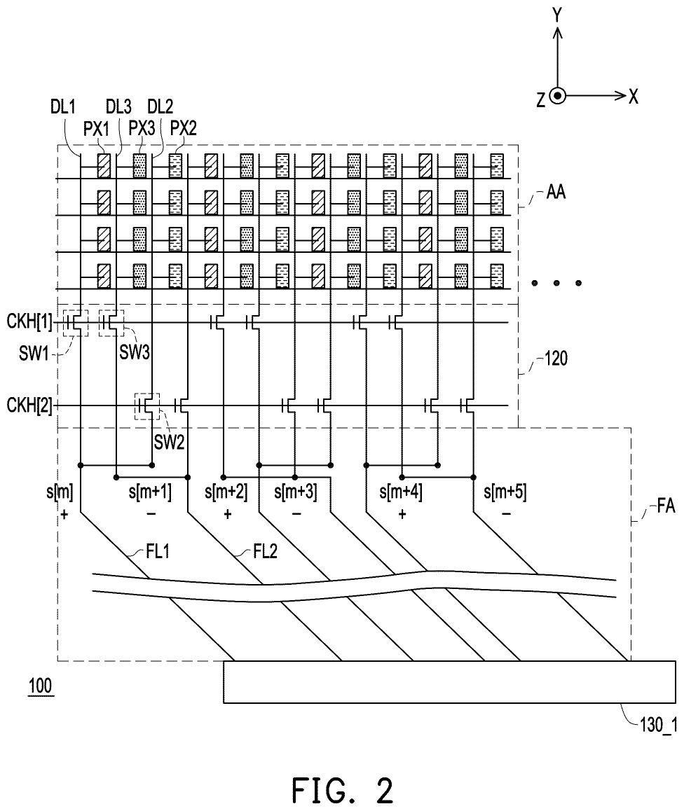

FIG. 1 shows a block diagram of an electronic device according to an embodiment of the disclosure. FIG. 2 shows a detailed schematic diagram of the electronic device of the embodiment of FIG. 1. Referring to FIG. 1 and FIG. 2, an electronic device 100 is, for example, a display device having a variable refresh rate (VRR) function. The VRR function may dynamically adjust a refresh rate of the display device, referred to as frequency conversion.

Therefore, the electronic device 100 may switch between multiple different refresh rates within a default time range. For example, the refresh rate of the electronic device 100 may vary within a range of 60 Hz and 360 Hz (e.g., 60 Hz, 90 Hz, 120 Hz, 240 Hz, 360 Hz, etc.). None of the above values shall be used to limit the disclosure.

Specifically, the electronic device 100 includes a substrate 110, a first fan-out line FL1, a second fan-out line FL2, and a multiplexer circuit 120. The substrate 110 has an active area AA and a fan-out area FA. The first fan-out line FL1 is located in the fan-out area FA. The second fan-out line FL2 is located in the fan-out area FA. The multiplexer circuit 120 is located between the active area AA and the fan-out area FA. The multiplexer circuit 120 is coupled to the first fan-out line FL1 and the second fan-out line FL2. The first fan-out line FL1 receives a first data signal S[m], and the second fan-out line FL2 receives a second data signal S[m+1].

The electronic device 100 also includes a data driver 130_1 and a data driver 130_2. The data drivers 130_1 and 130_2 are connected to the active area AA through the fan-out area FA and the multiplexer circuit 120. As shown in FIG. 2, the data driver 130_1 is used to output first data signals S[m], S[m+2], and S[m+4] and second data signals S[m+1], S[m+3], S[m+5] to drive corresponding display units PX1, PX2, and PX3. Polarities of the first data signal S[m] and the second data signal S[m+1] are opposite. For example, the first data signals S[m], S[m+2], S[m+4] are data signals having positive polarity, and the second data signal S[m+1], S[m+3], S[m+5] are data signals having negative polarity. Or, the first data signals S[m], S[m+2], and S[m+4] are data signals having negative polarity, and the second data signals S[m+1], S[m+3], and S[m+5] are data signals having positive polarity, where m is a positive integer greater than 0.

The electronic device 100 also includes a first data line DL1, a second data line DL2, and a third data line DL3. The first data line DL1, the second data line DL2, and the third data line DL3 are located in the active area AA, and arranged in a direction X perpendicular to the first data line DL1. The third data line DL3 is located between the first data line DL1 and the second data line DL2. The first data line DL1 and the second data line DL2 receive the first data signal S[m] through the first fan-out line FL1 and the multiplexer circuit 120. The third data line DL3 receives the second data signal S[m+1] through the second fan-out line FL2 and the multiplexer circuit 120.

Specifically, the multiplexer circuit 120 includes a first switching element SW1, a second switching element SW2, and a third switching element SW3. The first switching element SW1 is coupled to the first data line DL1 and the first fan-out line FL1. The second switching element SW2 is coupled to the second data line DL2 and the first fan-out line FL1. The third switching element SW3 is coupled to the third data line DL3 and the second fan-out line FL2. A first control signal CKH[1] is used to control a conduction state of the first switching element SW1 and the third switching element SW3. For example, the first switching element SW1 and the third switching element SW3 can be turned on according to a high level or low level of the first control signal CKH[1].

On the other hand, a second control signal CKH[2] is used to control a conduction state of the second switching element SW2. For example, the second switching element SW2 can be turned on according to the high level or low level of the second control signal CKH[2].

In this embodiment, since the first data line DL1 and the second data line DL2 receive the first data signal S[m] through the first fan-out line FL1 and the multiplexer circuit 120, the first switching element SW1 and the second switching element SW2 are turned on at different times. For example, when the first data signal S[m] is to be written into a display unit coupled to the first data line DL1, the first switching element SW1 will be turned on, so that the first data signal S[m] can be transmitted to the first data line DL1 through the multiplexer circuit 120. At this time, the second switching element SW2 will be turned off to prevent the first data signal S[m] from being transmitted to the second data line DL2. On the contrary, when the first data signal S[m] is to be written into a display unit coupled to the second data line DL2, the second switching element SW2 will be turned on, so that the first data signal S[m] can be transmitted to the second data line DL2 through the multiplexer circuit 120. At this time, the first switching element SW1 will be turned off to prevent the first data signal S[m] from being transmitted to the first data line DL1.

On the other hand, the first switching element SW1 and the third switching element SW3 can be turned on by the first control signal CKH[1] at the same time, so that the first data signal S[m] and the second data signal S[m+1] can be transmitted through the multiplexer circuit 120 to the first data line DL1 and the third data line DL3 respectively.

The electronic device 100 also includes a first display unit PX1, a second display unit PX2, and a third display unit PX3. The first display unit PX1, the second display unit PX2, and the third display unit PX3 are located in the active area AA and are coupled to the first data line DL1, the second data line DL2, and the third data line DL3 respectively. The first data signal S[m] is used to drive the first display unit PX1 and the second display unit PX2 to display corresponding image content. The second data signal S[m+1] is used to drive the third display unit PX3 to display corresponding image content. In an embodiment, the electronic device may be a liquid crystal display, and the display unit may be a sub-pixel of the liquid crystal panel. In another embodiment, the electronic device may be an organic light emitting diode display, and the display unit may be a light emitting diode, but not limited thereto.

The first display unit PX1, the second display unit PX2, and the third display unit PX3 can output lights of different colors. For example, the first display unit PX1, the second display unit PX2, and the third display unit PX3 are red pixels, green pixels, and blue pixels respectively, which output red, green, and blue light when driven.

In FIG. 1, it is illustrated by way of example that the electronic device 100 includes two data drivers 130_1 and 130_2, but the disclosure is not limited thereto. In an embodiment, the electronic device 100 may also include one data driver or other number of data drivers to drive the display unit. In addition, in FIG. 2, a layout structure in which the data driver 130_1 is connected to the active area AA through the fan-out area FA and the multiplexer circuit 120 is illustrated by way of example, and a layout structure in which the data driver 130_2 is connected to the active area AA through the fan-out area FA and the multiplexer circuit 120 may also be deduced in this way.

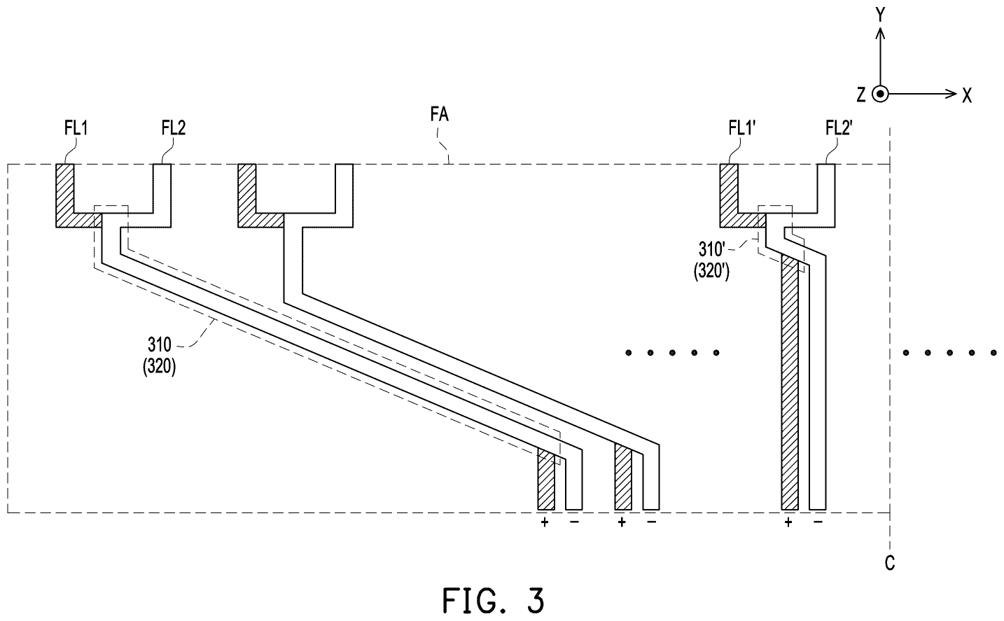

FIG. 3 shows a schematic diagram of a fan-out line of the embodiment of FIG. 1. Referring to FIG. 3, the first fan-out line FL1 has a first segment 310. The second fan-out line FL2 has a second segment 320. A projection of the first segment 310 overlaps a projection of the second segment 320 in a vertical direction of the substrate 110, where the vertical direction of the substrate 110 is a Z direction.

In this embodiment, taking the leftmost group of first fan-out line FL1 and second fan-out line FL2 of equal line width in FIG. 3 as an example, a ratio of a length of the first segment 310 to a length of the shorter of the first fan-out line FL1 and the second fan-out line FL2 (e.g., the first fan-out line FL1) may be a maximum of 99%. Take the rightmost group of first fan-out line FL1′ and second fan-out line FL2′ of equal line width in FIG. 3 as an example, a ratio of a length of a first segment 310′ to a length of the shorter of the first fan-out line FL1′ and the second fan-out line FL2′ (e.g., the first fan-out line FL1′) may be a minimum of 15%.

That is, the ratio of the length of the first segment 310 to the shorter of the first fan-out line FL1 and the second fan-out line FL2 is between 15% and 99% (15%≤the ratio of the length≤99%). Compared to the fan-out lines FL1, FL2, the fan-out lines FL1′, FL2′ are closer to the intermediate line C of the fan-out zone FA. the closer the fan-out lines FL1′, FL2′ are to the intermediate line C of the fan-out zone FA, the smaller the proportion of the lengths of the fan-out lines FL1′, FL2′ is, e.g., 15%. The further away from the centerline C of the fan-out zone FA the fan-out lines FL1, FL2 are, the greater the proportion of their lengths, e.g. 99%. Compared with the fan-out lines FL1 and FL2, the fan-out lines FL1′ and FL″ are closer to a center line C of the fan-out area FA. The closer the fan-out lines FL1′ and FL2′ are to the center line C of the fan-out area FA, the smaller their ratio of the length is, for example, 15%. The farther away the fan-out lines FL1 and FL2 are from the center line C of the fan-out area FA, the greater their ratio of the length is, for example, 99%.

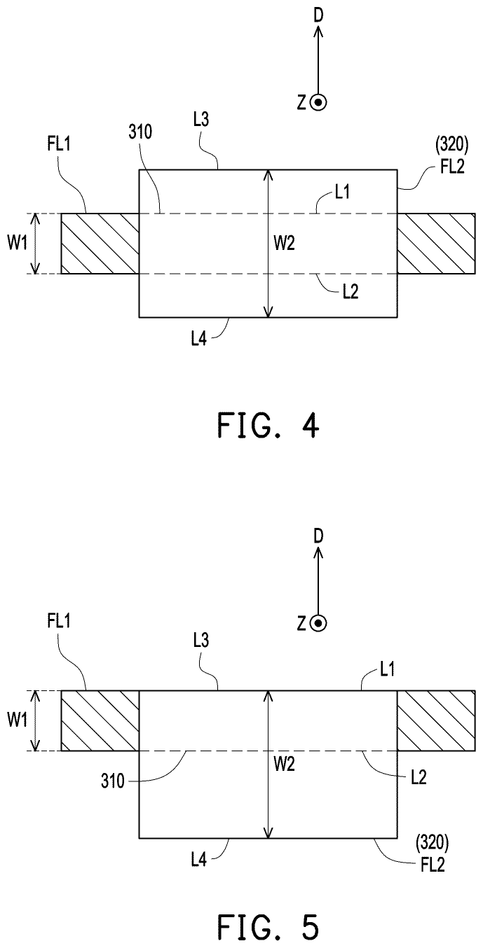

FIG. 4 shows a schematic diagram of a partial segment of a fan-out line according to an embodiment of the disclosure. Referring to FIG. 3 and FIG. 4, in the embodiment of FIG. 3, the fan-out lines FL1 and FL2 of equal line width are used as an illustration, but the disclosure is not limited thereto. In the embodiment of FIG. 4, the line widths of the fan-out lines FL1 and FL2 may also be unequal.

Specifically, in this embodiment, the first fan-out line FL1 has a smaller line width W1 in a direction D perpendicular to a first long side L1, and the second fan-out line FL2 has a larger line width W2 in the direction D perpendicular to the first long side L1. Taking overlapping segments as an example, a projection of the first segment 310 in a vertical direction Z of the substrate 110 includes the first long side L1 and the second long side L2, and a projection of the second segment 320 in the vertical direction Z of the substrate 110 includes a third long side L3 and a fourth long side L4. In the direction D perpendicular to the first long side L1, the first long side L1 is located between the third long side L3 and the second long side L2, and the second long side L2 is located between the first long side L1 and the fourth long side L4.

FIG. 5 shows a schematic diagram of a partial segment of a fan-out line according to another embodiment of the disclosure. Referring to FIG. 4 and FIG. 5. In the embodiment of FIG. 5, the line widths of the fan-out lines FL1 and FL2 are also unequal. Specifically, in this embodiment, in the direction D perpendicular to the first long side L1, the first long side L1 and the third long side L3 coincide with each other, and the second long side L2 is located between the first long side L1 and the fourth long side L4.

To sum up, in the embodiment of the disclosure, in the fan-out area, adjacent fan-out lines transmitting signals of different polarities have overlapping segments to reduce a voltage difference when signals of different polarities are transmitted to the data line. By increasing the area of the overlapping segments, the difference in the lengths of the two adjacent fan-out lines may be shortened, thereby reducing the uneven voltage distribution of polarity signals on the data line. In addition, near the middle of the fan-out area, the shorter the lengths of the two adjacent fan-out lines are, the smaller the area of the overlapping segment may be designed to be.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a substrate, having an active area and a fan-out area;
a first fan-out line, located in the fan-out area and having a first segment;
a second fan-out line, located in the fan-out area and having a second segment, wherein a projection of the first segment overlaps a projection of the second segment in a vertical direction of the substrate; and
a multiplexer circuit, located between the active area and the fan-out area, and coupled to the first fan-out line and the second fan-out line,
wherein the first fan-out line receives a first data signal, the second fan-out line receives a second data signal, and polarities of the first data signal and the second data signal are opposite.

2. The electronic device according to claim 1 further comprising:
a first data line, located in the active area and receiving the first data signal through the first fan-out line and the multiplexer circuit; and
a second data line, located in the active area and receiving the first data signal through the first fan-out line and the multiplexer circuit.

3. The electronic device according to claim 2, wherein the multiplexer circuit comprises:
a first switching element, coupled to the first data line and the first fan-out line, and being turned on according to a first control signal; and
a second switching element, coupled to the second data line and the first fan-out line, and being turned on according to a second control signal,
wherein the first switching element and the second switching element are turned on at different times.

4. The electronic device according to claim 2 further comprising:
a first display unit, located in the active area and coupled to the first data line; and
a second display unit, located in the active area and coupled to the second data line,
wherein the first display unit and the second display unit output lights of different colors.

5. The electronic device according to claim 2 further comprising:
a third data line, located in the active area and receiving the second data signal through the second fan-out line and the multiplexer circuit.

6. The electronic device according to claim 5, wherein the third data line is located between the first data line and the second data line.

7. The electronic device according to claim 5, wherein the multiplexer circuit comprises:
a third switching element, coupled to the third data line and the second fan-out line, and being turned on according to a first control signal.

8. The electronic device according to claim 1, wherein the projection of the first segment in the vertical direction of the substrate comprises a first long side and a second long side, and the projection of the second segment in the vertical direction of the substrate comprises a third long side and a fourth long side,
wherein in a direction perpendicular to the first long side, the first long side is located between the third long side and the second long side, and the second long side is located between the first long side and the fourth long side.

9. The electronic device according to claim 1,
wherein the projection of the first segment in the vertical direction of the substrate comprises a first long side and a second long side, and the projection of the second segment in the vertical direction of the substrate comprises a third long side and a fourth long side,
wherein in a direction perpendicular to the first long side, the first long side coincides with the third long side, and the second long side is located between the first long side and the fourth long side.

10. The electronic device according to claim 1, wherein a ratio of a length of the first segment to a length of the shorter of the first fan-out line and the second fan-out line is between 15% and 99%.

11. A circuit layout structure on a substrate of an electronic device, wherein the electronic device comprises the substrate and a multiplexer circuit, the substrate has an active area and a fan-out area, and the circuit layout structure comprises:
a first fan-out line, located in the fan-out area and having a first segment; and
a second fan-out line, located in the fan-out area and having a second segment, wherein a projection of the first segment overlaps a projection of the second segment in a vertical direction of the substrate, wherein a multiplexer circuit is located between the active area and the fan-out area, and is coupled to the first fan-out line and the second fan-out line,
wherein the first fan-out line receives a first data signal, the second fan-out line receives a second data signal, and polarities of the first data signal and the second data signal are opposite.

12. The circuit layout structure on the substrate of the electronic device according to claim 11 further comprising:
a first data line, located in the active area and receiving the first data signal through the first fan-out line and the multiplexer circuit; and
a second data line, located in the active area and receiving the first data signal through the first fan-out line and the multiplexer circuit.

13. The circuit layout structure on the substrate of the electronic device according to claim 12, wherein the multiplexer circuit comprises:
a first switching element, coupled to the first data line and the first fan-out line, and being turned on according to a first control signal; and
a second switching element, coupled to the second data line and the first fan-out line, and being turned on according to a second control signal,
wherein the first switching element and the second switching element are turned on at different times.

14. The circuit layout structure on the substrate of the electronic device according to claim 12, wherein the electronic device further comprises:
a first display unit, located in the active area and coupled to the first data line; and
a second display unit, located in the active area and coupled to the second data line,
wherein the first display unit and the second display unit output lights of different colors.

15. The circuit layout structure on the substrate of the electronic device according to claim 12 further comprising:
a third data line, located in the active area and receiving the second data signal through the second fan-out line and the multiplexer circuit.

16. The circuit layout structure on the substrate of the electronic device according to claim 15, wherein the third data line is located between the first data line and the second data line.

17. The circuit layout structure on the substrate of the electronic device according to claim 15, wherein the multiplexer circuit comprises:
a third switching element, coupled to the third data line and the second fan-out line, and being turned on according to a first control signal.

18. The circuit layout structure on the substrate of the electronic device according to claim 11, wherein the projection of the first segment in the vertical direction of the substrate comprises a first long side and a second long side, and the projection of the second segment in the vertical direction of the substrate comprises a third long side and a fourth long side,
wherein in a direction perpendicular to the first long side, the first long side is located between the third long side and the second long side, and the second long side is located between the first long side and the fourth long side.

19. The circuit layout structure on the substrate of the electronic device according to claim 11,
wherein the projection of the first segment in the vertical direction of the substrate comprises a first long side and a second long side, and the projection of the second segment in the vertical direction of the substrate comprises a third long side and a fourth long side,
wherein in a direction perpendicular to the first long side, the first long side coincides 5 with the third long side, and the second long side is located between the first long side and the fourth long side.

20. The circuit layout structure on the substrate of the electronic device according to claim 11, wherein a ratio of a length of the first segment to a length of the shorter of the first fan-out line and the second fan-out line is between 15% and 99%.
